(19) United States
(12) Patent Application Publication
(10) Pub. No.: US 2007/0263368 A1
(43) Pub. Date: Nov. 15, 2007

(54) Device Comprising a Non-Detachable Electronic Device

(75) Inventor: Stephane Ottobon, St Cyr Sur Mer (FR)

Correspondence Address: BUCHANAN, INGERSOLL & ROONEY PC, POST OFFICE BOX 1404, ALEXANDRIA, VA, 22313-1404, US

(73) Assignee: Gemplus, Gemenos (FR)

(21) Appl. No.: 11/666,879

(22) PCT Filed: Oct. 20, 2005
(86) PCT No.: PCT/EP05/55435

§ 371 Date: May 2, 2007

(30) Foreign Application Priority Data
Nov. 3, 2004 (FR) 0452507

(51) Int. Cl. H05K 7/00

(52) U.S. Cl. 361/760

(57) ABSTRACT

The invention relates to an electronic device comprising a module which is affixed to a support body by means of a layer of adhesive. According to the invention, the module comprises a support film having a first metallisation on an upper face and a printed circuit chip on a lower face, said chip being connected to the first metallisation through the film. The invention is characterised in that the device comprises a primer separation layer (9, 14) which is disposed between the lower face (10) and the chip (8). The invention is also characterised in that the primer separation layer adheres more to the adhesive layer than the film. The invention also relates to the associated modules.

This invention relates to a device comprising an electronic module non-detachable from a support without destruction of the latter and the associated module.

In particular, it relates to an electronic device comprising a module which is affixed to a support body by means of an adhesive; the module comprises a support film having a first metallisation on an upper face and a printed circuit chip on a lower face, said chip being connected to the first metallisation through the film.

It finds an application particularly in chip cards requiring security in disassembling the micromodule from the card body, whether for bank uses, identity or others.

Within an international context of major growth of security and authentication in addition to identity, manufacturers of chip cards have a duty to offer their customers chip cards in which it is not possible to tear the micromodule of f its card without damaging or destroying it.

Disassembly of the micromodule is already rendered impossible without destroying the latter by other techniques such as structural gluing or also by mechanical anchoring of the chip in a resin which is interdependent of the cavity bottom of a plastic card body. Therefore, during tearing off of the module, the chip remains adhering to the cavity bottom, being disconnected from the contact areas and disconnected from the dielectric support film.

Efficient structural gluing is only possible with a limited number of materials such as PVC. No effective gluing exists for a certain polymer material in particular, PET, which is particularly suitable for cards with a long service life such as cards implementing an identity application.

The aim of the invention is to offer a device comprising an electronic module on a support, which is endowed with an effective anti-separation function regardless of the nature of the support.

To this end, the aim of the invention is an electronic device of the type above, which is distinguished by the fact that it comprises a primer separation layer arranged between the lower face of the film and the chip and that the layer adheres more to the adhesive insertion layer than to the film.

The aim of the invention is also two types of electronic module comprising a support film with a first metallisation on an upper face and a printed circuit chip on a lower face, said chip being connected to the first metallisation through the film.

The first is distinguished by the fact that it comprises a non-metallic primer separation layer arranged between the lower face and the chip.

The second is distinguished by the fact that the primer separation layer arranged between the lower face and the chip has resistance to peeling of between approximately 1 and 5 N/cm whether it is metallic or not.

The invention is applicable to printed circuits.

The invention has the advantage of not modifying the current methods of module insertion in a card body. In particular, in a double-face version with a function with and without contact. All that is necessary is to choose particular adhesion forces of the various different constituents.

The invention is described in relation to examples illustrated in the following figures:

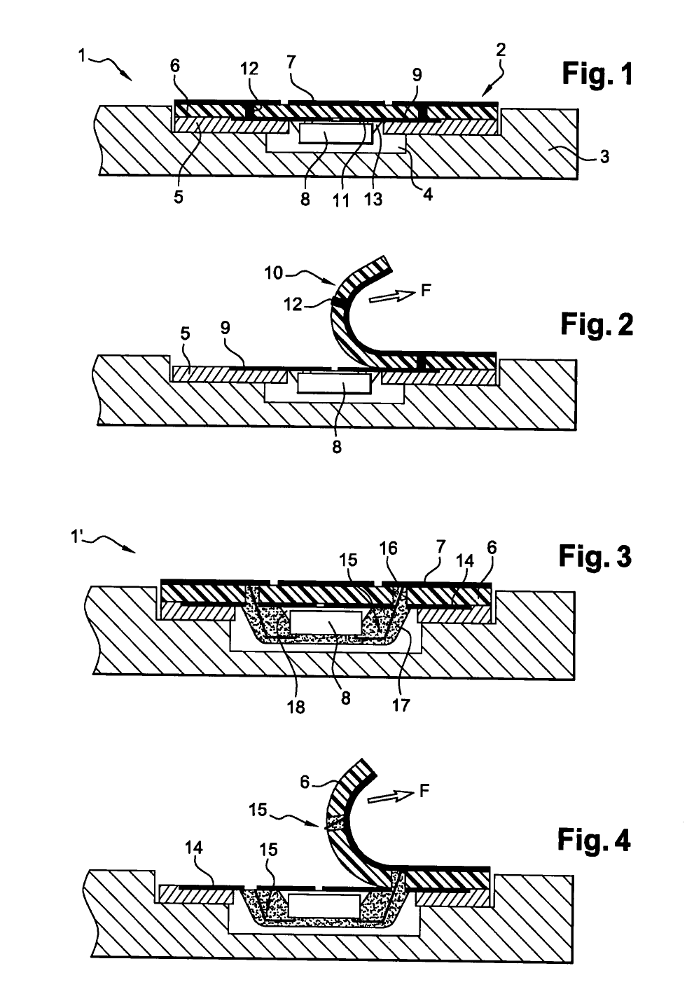

FIG. 1 illustrates a device of the invention according to a first method of realisation, the chip being installed on the front face;

FIG. 2 illustrates the behaviour of the device in FIG. 1 on tearing off of the module;

FIG. 3 illustrates a device of the invention according to a second method of realisation, the chip being installed on the rear face;

FIG. 4 illustrates the behaviour of the device in FIG. 3 on tearing off of the module;

In FIG. 1, the electronic device 1 of the invention comes in the form of a chip card. The card conventionally comprises an electronic module or micromodule 2 fixed to a card body 3, particularly in a cavity 4 arranged in the body. The fixing uses an adhesive 5, particularly in the form of a layer or film of the hot-melting or heat-adhesive type, known as “hotmelt” with if appropriate a heat-hardening phase preventing further melting or softening and detachment under the influence of heat.

A form other than a layer may possibly be considered for the glue for example, stripes, beads of glue, spot of glue, for example of the cyanoacrylate type. As a way of simplification, the expression “layer of glue” will be used to denote any means and form of gluing.

The adhesive is preferably fixed to the module, particularly when still in ribbon form. The module is subsequently cut to the desired shape extracted from the ribbon and inserted in the card body cavity.

The adhesive is preferably chosen in such a ways as to resist flexion/torsion stresses imposed by the currently applicable standard for chip cards, in the present case ISO 7816. The adhesive gives a resistance to peeling which is generally between approx. 10 and 30 N/cm. The peeling test consists for example in gluing a band of 1 cm wide and subsequently pulling it (with an angle of 90° for example) and recording the force in Newtons (N) required in order to detach the band.

As for the module 2, it comprises a dielectric support film 6, particularly made of polyimide or a glass/epoxy compound or PET or PEN, comprising an upper and lower face (in the direction of the figure). A first metallisation 7 is fixed to its upper face whilst a printed circuit chip 8 is fixed by gluing to its lower face.

The metallisation 7, particularly made of copper, is formed in the example by electric contact areas, designed to be read by an external reader. The chip is connected to the first metallisation through the film. These areas may be obtained by lamination of a layer of copper on to the dielectric followed by chemical etching. Any metallic pattern may be created by different methods known to the man of the trade, for example by mechanical cutting or by chemical etching, or even by serigraphy of a conductive material.

The metallisation 7 may also be a communication interface in the form of an antenna.

According to the invention, the device comprises a primer separation layer 9 (or an interposition element) arranged between the lower face 10 of the dielectric and the chip 8. The separation layer 9 in the example is a second metallisation performed in particular in the same manner as the first metallisation (by lamination, the lower metallisation may also be a metallic layer deposited by electrochemistry) but with a different pattern and specific adhesion. The module is known in this case as a “double face”.

The primer layer and the adhesives involved are selected such that the primer separation layer adheres more to the adhesive insertion layer than to the film.

For proper functioning of the invention, it is recommended to have at least a significant deviation of the adhesion forces of the primer separation layer in relation to the adhesive insertion layer and the dielectric film, for example at least on the order of 1 to 2 N/cm.

According to a characteristic, the primer separation layer presents adhesion to the dielectric of less than 8 N/cm). This value of 8 N/cm2 is generally used for adhesion of a metallisation to a dielectric. In the example, it is preferred to have adhesion of the separation layer to the dielectric of between 3 and 5 N/cm); this allows a good compromise between the capacity to prime the separation, taking account of the adhesive power of the insertion adhesive used and a good mechanical hold of the module in relation to the flexion/torsion stresses of its support and other standardised tests.

The chip rests at least in part on this separation layer. In the example, the chip is fixed facing forwards on to this separation layer such that its electric contacts 11 (commonly known as “bumps”) are connected to it (a connection method by flip chip). For fixing, one may use an adhesive 13 which becomes a conductor as a function of the pressure or a non-conductive glue or anisotropic conductive glue for example.

Furthermore, the primer separation layer also has an adhesion to the insertion adhesive 5 greater than or equal to 10 N/cm).

Preferably, an adhesive and/or means of anchoring of the separation layer in the adhesive are used such that the adhesive force or conversely the peeling force is between 10 and 30 N/cm. It may be greater than 30 N/cm.

The module comprises metallised screws 12 passing through the dielectric and establishing a connection between the contact areas and the metallic separation layer.

In FIG. 2, tearing away of the module caused by a force F results in separation of the dielectric in relation to the separation layer which remains adhering in the cavity with the chip. The metallised screws 12 are sectioned and the module becomes unusable.

In FIG. 3, another device 1′ comprises a chip 8 fixed by its rear face (opposite the connection contacts) by an adhesive 18 to the second metallisation 14. The chip is directly connected to the contact areas by means of conductive wires 15 which pass through the dielectric at the level of perforations 16 in order to access the contact areas. The chip preferably comprises a coating 17, particularly made of resin, designed to protect the chip and the electrical connections.

The metallisation may represent electric tracks designed to connect the chip to an antenna, particularly by means of conductive screws passing through the body. The antenna may be inserted in laminated sheets forming the body.

The antenna may also be formed of the primer separation layer in the shape of a spiral. In this case, the module constitutes a module with two communication interfaces with and without a contact.

In FIG. 4, tearing away of the module caused in the same manner as above results in separation of the dielectric 6 in relation to the separation layer 14 which remains adhering in the cavity with the chip. The connections 15 to the first metallisation are severed and render the module unusable in its contact function. On the other hand, a possible contact-free function in the case of a card with two interfaces may continue to operate.

The module is no longer transposable to another card body cavity for fraud purposes.

Generally speaking, the module may comprise a primer separation layer which is non-metallic or electrically insulating. The layer may be replaced with an interposition element with a specific pattern, for example a spiral, checkering etc.

The separation layer may comprise a surface state, particularly following abrasive or acid treatment or plasma or polishing in order to vary the adhesion of its faces and improve the efficacy of the anti-separation function. Controlled use of the various different adherences is within the scope of the man of the trade.

The separation layer may comprise means of mechanical anchoring in the adhesive in order to improve adhesion by mechanical anchoring and augment the adherence deviation with the dielectric.

A metallisation in the form of double-face copper or an interposition element must be of dimensions such that a portion of the latter is opposite the insertion adhesion in order to be caught in the adhesive mass interdependently with the card body. The surface of the primer separation layer may be equivalent to that of the module. It may in particular extend to the edge of the module.

The separation phenomenon may only be obtained if a specific design of the micromodule exists with regard to adhesion (or mechanical attachment) between the interposition element and the dielectric and specific properties of the adhesive used during insertion in relation to the surface and the material of the card body. It is indeed the combination of all these parameters in well-targeted adhesion ranges which allow destruction of the system during an attempt at disassembly.

Control of the adhesive power of the double-face copper or the interposition element on the dielectric may be performed via the choice of the adhesive material and its adhesive power or by subsequent modification of its adhesion, for example, weakening of the adhesive interface by heating. Control of the adhesive power may also be performed by using a dielectric which is easy to separate by its nature (owing to the fact that it presents difficult adhesion), such as for example PET (polyethylene terephthalate) or PEN (polyethylene naphthalate of the group of the polyesters but with greater temperature resistance than PET).

It has been observed that separation of the primer separation layer is all the more easy in that the dielectric is more flexible than the primer separation layer (for example, a primer separation layer made of copper is characterised by a Young module of less than approximately 100000 Mpa and a dielectric in polyether has a Young module on the order of 1000 Mpa).

The principle of the invention may be extended to separation of any element interposing the chip affixed to an insulating support or substrate; this may of course be the case of the copper on a plate of a single or multiple layer printed circuit.

The printed circuit may in the same manner comprise a primer separation layer between a chip or any component and metallisation. To this end, the printed circuit which comprises metallisation on a dielectric plate and at least one electric/electronic component connected to this metallisation, also comprises the primer separation layer placed between the components and the dielectric plate.

1. An electronic device comprising a module affixed to a support body by means of an insertion adhesive layer, said module comprising a support film having a first metallisation on an upper face and a printed circuit chip on a lower face, said chip being connected to the first metallisation through the film,
further comprising a primer separation layer arranged between the lower face and the chip wherein the layer adheres more to the insertion adhesive layer than to the film.

2. A device according to claim 1, wherein the primer separation layer presents a force of adhesion to the dielectric of less than 8 N/cm.

3. A device according to claim 1, wherein the primer separation layer presents a force of adhesion to the dielectric of between 3 and 5 N/cm.

4. A device according to claim 1, wherein the primer separation layer presents adhesion to the adhesive greater than 10 N/cm.

5. A device according to claim 1, wherein the primer separation layer forms a second metallisation of the film.

6. A device according to claim 5, wherein the chip is also connected to the second metallisation.

7. A device according to claim 6, wherein the second metallisation presents a spiralled antenna pattern.

8. An electronic module comprising a support film having a first metallisation on an upper face and a printed circuit chip connected to the first metallisation through the film, further comprising a non-metallic primer separation layer arranged between the lower face and the chip.

9. An electronic module comprising a support film having a first metallisation on an upper face and a printed circuit chip on a lower face, said chip being connected to the first metallisation through the film, further comprising a primer separation layer arranged between the lower face and the chip presenting resistance to peeling of between approximately 1 and 5 N/cm.

10. A module according to claim 9, wherein the primer separation layer comprises a second metallisation of the film.

11. A module according to claim 10, wherein the chip is also connected to the second metallisation, said second metallisation presenting a spiralled antenna pattern.

12. A printed circuit comprising a metallisation on a dielectric plate and at least one electric/electronic component connected to said metallisation, further comprising a primer separation layer placed between the component and the dielectric plate.
